(19) United States
(12) Patent Application Publication
(10) Pub. No.: US 2025/0382217 A1
(43) Pub. Date: Dec. 18, 2025

(54) GLASS CERAMIC SUBSTRATE, GREENSHEET FOR GLASS CERAMIC SUBSTRATE, AND COMPOSITE POWDER FOR GLASS CERAMIC SUBSTRATE

(71) Applicant: NIPPON ELECTRIC GLASS CO., LTD., Otsu-shi, Shiga (JP)

(72) Inventor: Takahisa YAMAGUCHI, Otsu-shi, Shiga (JP)

(73) Assignee: NIPPON ELECTRIC GLASS CO., LTD., Otsu-shi, Shiga (JP)

(21) Appl. No.: 18/877,550

(22) PCT Filed: Jul. 18, 2023
(86) PCT No.: PCT/JP2023/026174

§ 371 Date: Dec. 20, 2024

(30) Foreign Application Priority Data
Jul. 19, 2022 (JP) 2022-114475

(51) Int. Cl. C03C 10/00

(52) U.S. Cl. CPC C03C 10/0054

(57) ABSTRACT

A glass ceramic substrate according to the present invention is a glass ceramic substrate containing: a glass; a first ceramic filler; a second ceramic filler; and a crystalline material, in which the first ceramic filler is alumina, the second ceramic filler is cordierite, the crystalline material is anorthite, and (X-ray diffraction peak intensity of a (2-20) crystal plane of the anorthite)/(X-ray diffraction peak intensity of the (2-20) crystal plane of the anorthite+X-ray diffraction peak intensity of a (104) crystal plane of the alumina+X-ray diffraction peak intensity of a (100) crystal plane of the cordierite) is 0.15 or more.

### TECHNICAL FIELD

The present invention relates to a glass ceramic substrate, a green sheet for a glass ceramic substrate, and a composite powder for a glass ceramic substrate.

### BACKGROUND ART

In the related art, when testing a semiconductor wafer, a probe card is disposed on the semiconductor wafer and the semiconductor wafer is electrically connected to a tester via the probe card.

The probe card generally includes a test head to be in contact with a semiconductor wafer, a printed ceramic substrate to be connected to a tester, and a ceramic substrate called an interposer substrate for connecting the printed ceramic substrate to the test head. For example, Patent Literature 1 describes, as a ceramic substrate that can be fired at a low temperature, a ceramic substrate that contains a glass and a ceramic filler.

### CITATION LIST

### Patent Literature

Patent Literature 1: JP2009-074823A

### SUMMARY OF INVENTION

### Technical Problem

A distance between electrode pads on the printed ceramic substrate is larger than a distance between electrode pads on the test head. One main surface side of the interposer substrate is provided with electrode pads compatible with the electrode pads on the printed ceramic substrate, and the other main surface side thereof is provided with electrode pads compatible with the electrode pads on the test head. The electrode pads on the one main surface side and the electrode pads on the other main surface side are connected to each other via internal conductors. Therefore, it is important that the electrode pads on both main surfaces of the interposer substrate have high positional accuracy.

In particular, since via holes are formed in the interposer substrate and internal conductors are formed therein, it is difficult to maintain mechanical strength of the interposer substrate. Therefore, there is a demand for improving the mechanical strength of the ceramic substrate used as an interposer substrate.

In addition, tests using a probe card are carried out over a wide temperature range, for example, from −40° C. to +125° C. Therefore, it is preferable to bring a thermal expansion coefficient of the interposer substrate close to a thermal expansion coefficient of the test head or the printed ceramic substrate such that there is no difference between the distance between the electrode pads on the interposer substrate and the distance between the electrode pads on the test head or the printed ceramic substrate when the test temperature changes. Therefore, it is preferable that the interposer substrate is made of a material whose thermal expansion coefficient can be adjusted to suit the usage environment.

In addition, the test head generally has a thermal expansion coefficient close to a thermal expansion coefficient of the semiconductor wafer. Therefore, there is a demand for the thermal expansion coefficient of the ceramic substrate used as an interposer substrate to be reduced to approximately the same as the thermal expansion coefficient of the semiconductor wafer. However, the ceramic substrate described in Patent Literature 1 has a problem that it is difficult to achieve a low thermal expansion coefficient.

An object of the present invention is to provide a glass ceramic substrate that has high mechanical strength and has a low thermal expansion coefficient.

### Solution to Problem

As a result of careful consideration, the inventor of the present invention has found that when a glass and a specific ceramic filler are added to form a composite powder, which is then fired, a crystalline material is precipitated from the glass and is then used for a glass ceramic substrate, so that the above technical problems can be solved. Thus, the present invention has been proposed. Each aspect of a glass ceramic substrate, a green sheet for a glass ceramic substrate, and a composite powder for a glass ceramic substrates for solving the above problems will be described.

A glass ceramic substrate according to Aspect 1 contains: a glass; a first ceramic filler; a second ceramic filler; and a crystalline material, in which the first ceramic filler is alumina, and the second ceramic filler is cordierite, the crystalline material is anorthite, and (X-ray diffraction peak intensity of a (2-20) crystal plane of the anorthite)/(X-ray diffraction peak intensity of the (2-20) crystal plane of the anorthite+X-ray diffraction peak intensity of a (104) crystal plane of the alumina+X-ray diffraction peak intensity of a (100) crystal plane of the cordierite) is 0.15 or more. Here, the “(X-ray diffraction peak intensity of a (2-20) crystal plane of the anorthite)/(X-ray diffraction peak intensity of the (2-20) crystal plane of the anorthite+X-ray diffraction peak intensity of a (104) crystal plane of the alumina+X-ray diffraction peak intensity of a (100) crystal plane of the cordierite)” is a value obtained by dividing the X-ray diffraction peak intensity of the (2-20) crystal plane of the anorthite by a sum of the X-ray diffraction peak intensity of the (2-20) crystal plane of the anorthite, the X-ray diffraction peak intensity of the (104) crystal plane of the alumina, and the X-ray diffraction peak intensity of the (100) crystal plane of the cordierite.

A glass ceramic substrate according to Aspect 2 is based on Aspect 1, and preferably has three-point bending strength of 250 MPa or more. Here, the “three-point bending strength” refers to the strength measured on a sample having thickness of 3.0 mm using a method in accordance with JIS R1601 (2008).

A glass ceramic substrate according to Aspect 3 is based on Aspect 1 or Aspect 2, and preferably has a thermal expansion coefficient in a temperature range of from −40° C. to +125° C. of 4.0×10⁻⁶/° C. or less.

A glass ceramic substrate according to Aspect 4 is based on any one of Aspect 1 to Aspect 3, in which a maximum particle diameter of the cordierite as the second ceramic filler is preferably larger than a maximum particle diameter of the alumina as the first ceramic filler.

A glass ceramic substrate according to Aspect 5 is based on any one of Aspect 1 to Aspect 4, in which a value obtained by dividing the maximum particle diameter of the cordierite as the second ceramic filler by the maximum particle diameter of the alumina as the first ceramic filler is preferably from 1.5 to 10.0.

A glass ceramic substrate according to Aspect 6 is based on any one of Aspect 1 to Aspect 5, in which an average particle diameter of the cordierite as the second ceramic filler is preferably larger than an average particle diameter of the alumina as the first ceramic filler.

A glass ceramic substrate according to Aspect 7 is based on any one of Aspect 1 to Aspect 6, in which a value obtained by dividing the average particle diameter of the cordierite as the second ceramic filler by the average particle diameter of the alumina as the first ceramic filler is preferably from 1.5 to 10.0.

A glass ceramic substrate according to Aspect 8 is based on any one of Aspect 1 to Aspect 7, in which the glass preferably has a content of Al₂O₃ of 1.0 mol % or less.

A glass ceramic substrate according to Aspect 9 is based on any one of Aspect 1 to Aspect 8, in which the glass preferably contains, as a glass composition, in mol %, from 50% to 80% of SiO₂, from 5% to 30% of B₂O₃, and from 3% to 25% of CaO.

A green sheet for a glass ceramic substrate according to Aspect 10 is a green sheet for a glass ceramic substrate containing: a glass powder; a first ceramic filler; and a second ceramic filler, in which it is preferable that the first ceramic filler is alumina, and the second ceramic filler is cordierite, and a maximum particle diameter of the cordierite is larger than a maximum particle diameter of the alumina. In this case, a value obtained by dividing the maximum particle diameter of the cordierite by the maximum particle diameter of the alumina is particularly preferably from 1.5 to 10.0.

A green sheet for a glass ceramic substrate according to Aspect 11 is a green sheet for a glass ceramic substrate containing: a glass powder; a first ceramic filler; and a second ceramic filler, in which it is preferable that the first ceramic filler is alumina, and the second ceramic filler is cordierite, and an average particle diameter of the cordierite is larger than an average particle diameter of the alumina. In this case, a value obtained by dividing the average particle diameter of the cordierite by the average particle diameter of the alumina is particularly preferably from 1.5 to 10.0.

A composite powder for a glass ceramic substrate according to Aspect 12 is a composite powder for a glass ceramic substrate containing: a glass powder; a first ceramic filler; and a second ceramic filler, in which it is preferable that the first ceramic filler is alumina, and the second ceramic filler is cordierite, and a maximum particle diameter of the cordierite is larger than a maximum particle diameter of the alumina. In this case, a value obtained by dividing the maximum particle diameter of the cordierite by the maximum particle diameter of the alumina is particularly preferably from 1.5 to 10.0.

A composite powder for a glass ceramic substrate according to Aspect 13 is a composite powder for a glass ceramic substrate containing: a glass powder; a first ceramic filler; and a second ceramic filler, in which it is preferable that the first ceramic filler is alumina, and the second ceramic filler is cordierite, and an average particle diameter of the cordierite is larger than an average particle diameter of the alumina. In this case, a value obtained by dividing the average particle diameter of the cordierite by the average particle diameter of the alumina is particularly preferably from 1.5 to 10.0.

### Advantageous Effects of Invention

According to the present invention, it is possible to provide a glass ceramic substrate that has high mechanical strength and has a low thermal expansion coefficient.

### BRIEF DESCRIPTION OF DRAWINGS

FIG. 1 is a schematic cross-sectional view showing an example of a ceramic circuit board according to the present invention.

### DESCRIPTION OF EMBODIMENTS

Hereinafter, one example of a preferred embodiment of the present invention will be described. However, the following embodiment is merely an example. The present invention is not limited to the following embodiment in any way.

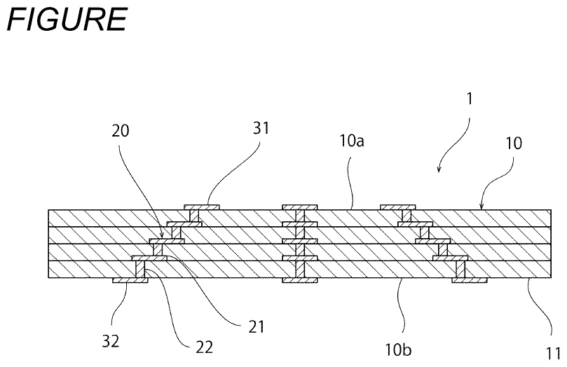

FIG. 1 is a schematic cross-sectional view showing an example of a ceramic circuit board according to the present invention. A ceramic circuit board 1 includes a glass ceramic substrate 10. The glass ceramic substrate 10 has first and second main surfaces 10a and 10b. The glass ceramic substrate 10 is composed of a laminate of a plurality of glass ceramic layers 11.

A plurality of internal conductors 20 are disposed within the glass ceramic substrate 10. Each of the internal conductors 20 includes an interlayer electrode 21 that is located between adjacent glass ceramic layers 11, and a via hole electrode 22 that penetrates the glass ceramic layer 11 and that connects the interlayer electrodes 21 facing each other in a laminating direction of the glass ceramic layers 11 via the glass ceramic layer 11.

The plurality of internal conductors 20 are provided across the first main surface 10a and the second main surface 10b of the glass ceramic substrate 10. An end portion of the internal conductor 20 on the first main surface 10a side is connected to an electrode pad 31 provided on the first main surface 10a. An end portion of the internal conductor 20 on the second main surface 10b side is connected to an electrode pad 32 provided on the second main surface 10b.

A distance between adjacent electrode pads 32 is longer than ta distance between adjacent electrode pads 31. Therefore, when the glass ceramic substrate 10 is used as an interposer substrate, a test head is connected to the second main surface 10b side, and a printed ceramic substrate is connected to the first main surface 10a side.

Note that, the internal conductor 20 and the electrode pads 31 and 32 may be made of an appropriate conductive material. The internal conductor 20 and the electrode pads 31 and 32 may each be made of at least one metal such as Pt, Au, Ag, Cu, Ni, or Pd.

The glass ceramic substrate 10 according to the present invention has three-point bending strength of preferably 250 MPa or more, and particularly preferably 320 MPa or more. When the three-point bending strength of the glass ceramic substrate is too low, mechanical strength of the glass ceramic substrate 10 is likely to decrease.

The glass ceramic substrate 10 according to the present invention contains a glass, a first ceramic filler, a second ceramic filler, and a crystalline material precipitated from a glass by firing, in which the first ceramic filler is alumina (Al₂O₃), the second ceramic filler is cordierite (2MgO·2Al₂O₃·5SiO₂), and the crystalline material precipitated from the glass is anorthite (CaO·Al₂O₃·2SiO₂).

In an X-ray diffraction pattern of the glass ceramic substrate 10 according to the present invention, (X-ray diffraction peak intensity of a (2-20) crystal plane of the anorthite)/(X-ray diffraction peak intensity of the (2-20) crystal plane of the anorthite+X-ray diffraction peak intensity of a (104) crystal plane of the alumina+X-ray diffraction peak intensity of a (100) crystal plane of the cordierite) is 0.15 or more, and preferably 0.20 or more. When this ratio is satisfied, the proportion of the anorthite precipitated in the glass ceramic substrate increases, and as a result, strength of the glass ceramic substrate is increased. Note that, the ratio can be calculated from an X-ray diffraction pattern obtained by measuring a sample, which is prepared by destroying the glass ceramic substrate into a powder or in a non-destructive manner, using an X-ray diffraction apparatus.

The alumina as the first ceramic filler in the glass ceramic substrate 10 according to the present invention has high strength and can therefore increase the strength of the glass ceramic substrate. In addition, when a composite powder is fired to obtain a glass ceramic substrate, softening and flowing of the glass corrodes the alumina in the glass, eluting the Al component in the alumina, and the Al component reacts with Ca in the glass to precipitate the anorthite. Since the anorthite is a high strength crystal, the strength of the glass ceramic substrate can be increased by precipitating the anorthite. On the other hand, when the content of the alumina is too high, since the content of the cordierite, which is a low thermal expansion filler, in the glass ceramic substrate is relatively decreased, a thermal expansion coefficient of the glass ceramic substrate is difficult to decrease. Specifically, it is difficult for the thermal expansion coefficient of the glass ceramic substrate to be 4.0×10⁻⁶/° C. or less. Therefore, in the glass ceramic substrate 10 according to the present invention, the content of the alumina as the first ceramic filler is preferably 15 vol % or more, more preferably 20 vol % or more, and is preferably 40 vol % or less, more preferably 35 vol % or less.

The cordierite as the second ceramic filler in the in the glass ceramic substrate 10 according to the present invention is a component that decreases the thermal expansion coefficient of the glass ceramic substrate. Therefore, the higher the proportion of the cordierite in the glass ceramic substrate, the lower the thermal expansion coefficient of the glass ceramic substrate. As a result, the thermal expansion coefficient of the glass ceramic substrate can be reduced to approximately a thermal expansion coefficient of a semiconductor wafer. Note that, since the thermal expansion coefficient of the semiconductor wafer (i.e., a silicon wafer) is 4.1×10⁻⁶/° C., in order to avoid warpage due to a difference in thermal expansion coefficient between the silicon wafer and the glass ceramic substrate, the thermal expansion coefficient of the glass ceramic substrate in a temperature range of from −40° C. to +125° C. is preferably 4.0×10⁻⁶/° C. or less. On the other hand, when the content of the cordierite is too high, there is a risk that the specific surface area of the cordierite is larger than that of the alumina. As a result, the deterioration of the cordierite due to corrosion of the glass is remarkable, making it difficult to achieve low thermal expansion of the glass ceramic substrate using the cordierite. Specifically, it is difficult for the thermal expansion coefficient of the glass ceramic substrate to be 4.0×10⁻⁶/° C. or less. Therefore, in the glass ceramic substrate 10 according to the present invention, the content of the cordierite as the second ceramic filler is preferably 10 vol % or more, more preferably 15 vol % or more, and is preferably 30 vol % or less, more preferably 25 vol % or less.

Since the cordierite contains Al₂O₃ as a component, when the cordierite is contained as a second ceramic filler in the glass ceramic substrate, during firing of a composite powder to obtain a glass ceramic substrate, the softening and flowing of the glass causes the cordierite in the glass to corrode, eluting the Al component in the cordierite, and the Al component reacts with Ca in the glass to precipitate a crystal of the anorthite. However, since the cordierite contains MgO and SiO₂ in the constituent components, the effect of precipitating a crystal of the anorthite (i.e., the amount of crystal precipitation) is inferior to that of the alumina. Accordingly, similar to the alumina filler, the strength of the glass ceramic substrate is increased, but the cordierite itself deteriorates, and the effect of decreasing the thermal expansion coefficient of the glass ceramic substrate decreases. Therefore, in the case of precipitating the anorthite, it is preferable to precipitate the anorthite from the alumina rather than the cordierite, from the viewpoint of decreasing the thermal expansion coefficient of the glass ceramic substrate.

In order to solve this problem, in a glass ceramic substrate, a green sheet for a glass ceramic substrate, and a composite powder for a glass ceramic substrate according to the present invention, a maximum particle diameter of the cordierite is preferably larger than a maximum particle diameter of the alumina. Specifically, a value obtained by dividing the maximum particle diameter of the cordierite by the maximum particle diameter of the alumina is preferably 1.5 or more, more preferably 2.0 or more, and is preferably 10.0 or less, more preferably 5.0 or less. As a result, it is possible to increase the specific surface area of the alumina relative to the cordierite, and as a result, it is possible to increase the amount of the crystal of the anorthite precipitated from the alumina in the glass. Accordingly, by preventing the deterioration of the cordierite due to corrosion of the glass while obtaining high strength of the glass ceramic substrate, it is possible to achieve low expansion of the glass ceramic substrate using the cordierite.

Similarly, in order to solve this problem, in the glass ceramic substrate, the green sheet for a glass ceramic substrate, and the composite powder for a glass ceramic substrate according to the present invention, an average particle diameter of the cordierite is preferably larger than an average particle diameter of the alumina. A value obtained by dividing the average particle diameter of the cordierite by the average particle diameter of the alumina is preferably 1.5 or more, more preferably 2.0 or more, and is preferably 10.0 or less, more preferably 5.0 or less. As a result, it is possible to increase the specific surface area of the alumina relative to the cordierite, and as a result, it is possible to increase the amount of the crystal of the anorthite precipitated from the alumina in the glass. Accordingly, by preventing the deterioration of the cordierite due to corrosion of the glass while obtaining high strength of the glass ceramic substrate, it is possible to achieve low expansion of the glass ceramic substrate using the cordierite.

Note that, in the present invention, the maximum particle diameters of the alumina and the cordierite in the glass ceramic substrate and the green sheet for a glass ceramic substrate are determined by observing a cross section of the glass ceramic substrate and a cross section of the green sheet for a glass ceramic substrate with a scanning electron microscope (SEM). In more detail, first, any 10 locations (no overlapping locations) are selected from each of the cross section of the glass ceramic substrate and the cross section of the green sheet for a glass ceramic substrate, and a particle having the largest particle diameter is selected from each of SEM images (magnification: 5000 times). Next, a maximum length of the particle is defined as X, a length connecting a perpendicular line at a midpoint of the maximum length X and two intersection points of an outer periphery of the particle is defined as Y, and “(X+Y)/2” is defined as a specific particle diameter at each location. Then, an average value of specific particle diameters at 10 locations is determined as the maximum particle diameter. In addition, in the present invention, the maximum particle diameters of the alumina and the cordierite in the composite powder for a glass ceramic substrate was determined by observation with a scanning electron microscope (SEM). In more detail, first, any one location is selected from the composite powder for a glass ceramic substrate, and SEM images (magnification: 5000 times) of any 10 locations (no overlapping locations) are obtained. In each of the SEM images, a particle having the largest particle diameter is selected. Next, a maximum length of the particle is defined as X, a length connecting a perpendicular line at a midpoint of the maximum length X and two intersection points of an outer periphery of the particle is defined as Y, and “(X+Y)/2” is defined as a specific particle diameter at each location. Then, an average value of specific particle diameters at 10 locations is determined as the maximum particle diameter.

In addition, in the present invention, the average particle diameter (D₅₀) refers to a value measured by a laser diffraction scattering method.

Note that, in a composite powder before firing for obtaining the glass ceramic substrate, the sizes of the alumina as the first ceramic filler and the cordierite as the second ceramic filler are not particularly limited. When the average particle diameters thereof are too large, a porosity of the glass ceramic substrate increases, and the mechanical strength is likely to decrease. On the other hand, when the average particle diameters thereof are too small, the handleability tends to be poor. Specifically, it is difficult to achieve uniform mixing and dispersion, which may lead to fluctuations in thermal expansion coefficient and mechanical strength. Therefore, the average particle diameter (D₅₀) of each ceramic filler is preferably 0.01 μm or more, more preferably 0.1 μm or more, still more preferably 0.5 μm or more, and is preferably 10 μm or less, more preferably 8 μm or less, still more preferably 5 μm or less.

Further, when the content of the alumina is larger than the content of the cordierite in the glass ceramic substrate, the above effects can be more effectively obtained.

In addition to the alumina as the first ceramic filler and the cordierite as the second ceramic filler, a third ceramic filler, for example, β-spodumene, mullite, willemite, or quartz, may be incorporated.

The glass is a component that increases the denseness (i.e., relative density) of the glass ceramic substrate. In the glass ceramic substrate, the content of the glass is preferably 35 vol % or more, more preferably 40 vol % or more, and is preferably 65 vol % or less, more preferably 60 vol % or less. When the content of the glass is too low, it is difficult to obtain the above effects of the glass. On the other hand, when the content of the glass is too high, the thermal expansion coefficient of the glass ceramic substrate increases, and the mechanical strength of the glass ceramic substrate is likely to decrease. In addition, when the content of the glass is too low, the mechanical strength of the glass ceramic substrate is likely to decrease.

The glass in the glass ceramic substrate preferably contains, as a glass composition, in mol %, from 50% to 80% of SiO₂, from 5% to 30% of B₂O₃, and from 3% to 25% of CaO. In the following description of the content range of each component, % refers to mol % unless otherwise specified. Unless otherwise stated, in the present description, a numerical range indicated using “to” means a range that includes the numerical values listed before and after “to” as the minimum value and the maximum value, respectively.

SiO₂ is a component that forms a glass network. The content of SiO₂ is preferably 50% or more, more preferably 55% or more, and is preferably 80% or less, more preferably 75% or less. When the content of SiO₂ is low, vitrification is difficult. On the other hand, when the content of SiO₂ is high, the softening point of the glass is high, making it difficult to obtain a glass ceramic substrate by low temperature firing.

B₂O₃ is a component that forms the glass network, that expands the vitrification range, and that stabilizes the glass. The content of B₂O₃ is preferably 5% or more, more preferably 10% or more, and is preferably 30% or less, more preferably 25% or less. When the content of B₂O₃ is low, the softening point of the glass is high, making it difficult to obtain a glass ceramic substrate by low temperature firing. On the other hand, when the content of B₂O₃ is high, the glass ceramic substrate tends to have a high thermal expansion coefficient.

CaO is a component that stabilizes the glass by strengthening the glass network and that improves the acid resistance of the glass. It is also a component that reacts with the alumina as the first ceramic filler to precipitate the anorthite to thereby increase the strength of the glass ceramic substrate when the composite powder is fired to obtain a glass ceramic substrate. The content of CaO is preferably 3% or more, more preferably 5% or more, and is preferably 25% or less, more preferably 15% or less. When the content of CaO is low, the amount of the anorthite precipitated from the glass is small, making it difficult to increase the strength of the glass ceramic substrate. On the other hand, when the content of CaO is high, the softening point is high, making it difficult to obtain a glass ceramic substrate by low temperature firing.

Al₂O₃ in the glass is a component that stabilizes the glass by strengthening the glass network and that improves the acid resistance of the glass. The content of Al₂O₃ is preferably 1.0% or less, more preferably 0.5% or less, and still more preferably less than 0.1%. When the content of Al₂O₃ in the glass is more than 1.0%, the glass network is too strong, and thereby the Ca component in the glass is difficult to elute. As a result, the reaction with the Al component in the alumina as the first ceramic filler is prevented, and the anorthite is less likely to precipitate.

Alkali metal oxides (Li₂O, Na₂O, and K₂O) are components that decrease the viscosity of the glass and that increase the meltability. The alkali metal oxides are also components that greatly decrease the softening point of the glass, and are components that greatly decrease the softening point of a glass ceramic substrate obtained by firing a composite powder containing the glass and a ceramic filler. The content of Li₂O+Na₂O+K₂O (total content of Li₂O, Na₂O, and K₂O) is preferably 1% or more, more preferably 2% or more, and is preferably 10% or less, more preferably 6% or less. When the content of Li₂O+Na₂O+K₂O is low, the effect of decreasing the viscosity of the glass is poor. On the other hand, when the content of Li₂O+Na₂O+K₂O is high, the water resistance tends to decrease. Note that, the content of Li₂O is preferably from 0% to 4%. The content of Na₂O is preferably from 0% to 4%. The content of K₂O is preferably from 0% to 6%.

Alkaline earth metal oxides (MgO, SrO, and BaO (excluding CaO)) are components that decrease the viscosity of the glass and that increase the meltability. The alkaline earth metal oxides are also components that decrease the softening point of the glass, and are components that decrease the softening point of a glass ceramic substrate obtained by firing a composite powder containing the glass and a ceramic filler. The content of MgO+SrO+BaO (total content of MgO, SrO, and BaO) is preferably 1% or more, more preferably 2% or more, and is preferably 20% or less, more preferably 10% or less. On the other hand, when the content of MgO+SrO+BaO is high, the glass is unstable, and the glass tends to undergo devitrification during melting. Note that, the content of MgO is preferably from 0% to 10%. The content of SrO is preferably from 0% to 10%. The content of BaO is preferably from 0% to 10%.

In addition to the above components, other components may be incorporated into the glass composition.

In the composite powder before firing for obtaining the glass ceramic substrate, the size of a glass powder is not particularly limited. When the average particle diameter of the glass powder is too large, once excessive heat energy is required to soften and flow the glass powder during firing, the glass powder remains unmelted, the porosity of the glass ceramic substrate increases, and the mechanical strength is likely to decrease. On the other hand, when the average particle diameter of the glass powder is too small, the handleability tends to be poor. Specifically, it is difficult to achieve uniform mixing and dispersion, which may lead to fluctuations in thermal expansion coefficient and mechanical strength. Therefore, the average particle diameter (D₅₀) of the glass powder is preferably 0.1 μm or more, more preferably 0.5 μm or more, still more preferably 1.0 μm or more, and is preferably 10 μm or less, more preferably 8 μm or less, still more preferably 5 μm or less. Here, the average particle diameter (D₅₀) refers to a value measured by a laser diffraction scattering method.

Next, a method for manufacturing the glass ceramic substrate 10 will be described.

First, a composite powder containing the above glass powder, alumina filler, and cordierite filler is prepared. Next, a binder containing a resin, a plasticizer, a solvent, or the like is added to this composite powder, and the mixture is kneaded to prepare a slurry. The slurry is formed into a sheet by a doctor blade method or the like to prepare a green sheet for a glass ceramic substrate.

Next, a via hole is formed in the green sheet. The via hole can be formed, for example, by irradiation with laser light, mechanical punching, or the like.

Next, the inside of the via hole is filled with a conductive paste for forming the via hole electrode 22. In addition, a conductive paste for forming the interlayer electrodes 21 and the electrode pads 31 and 32 is applied onto the green sheet.

Thereafter, the green sheets are appropriately laminated to obtain a laminate. The laminate is fired to cause the crystal of the anorthite to precipitate from the glass, thereby producing the glass ceramic circuit board 1 (glass ceramic substrate 10).

### EXAMPLES

Hereinafter, the present invention will be described in detail based on Examples. However, the present invention is not limited to the following Examples in any way, and can be modified and practiced as appropriate within the scope of the present invention.

Table 1 shows Examples of the present invention (sample Nos. 1 to 4) and Comparative Examples (sample Nos. 5 and 6).

Glass raw materials were mixed to have a glass composition containing, in mol %, 64% of SiO₂, 18% of B₂O₃, 16% of CaO, 1% of Na₂O, and 1% of K₂O, charged into a platinum crucible, and melted at 1450° C. to obtain a molten glass. Next, the molten glass was supplied between two water-cooled rotating rolls and subjected to stretch-forming to obtain a film shaped glass. The glass thus obtained was crushed in a ball mill to obtain a glass powder having an average particle diameter of 2.0 μm. Next, the glass powder, an alumina powder, and a cordierite powder were mixed in the ratios shown in the table to prepare a composite powder. Further, 2 mass % of methacrylic resin was added to the composite powder, which were mixed as an ethanol dispersion liquid. The granules obtained by drying ethanol were uniaxially pressed to prepare a green compact in the shape of a folding piece. The green compact was fired at 880° C. to obtain a fired body. The fired body was used to measure the X-ray diffraction peak intensity, the thermal expansion coefficient, and the three-point bending strength. The results are shown in Table 1.

TABLE 1

| Sample No. | | 1 | 2 | 3 | 4 | 5 | 6 |
|---|---|---|---|---|---|---|---|
| Constituent material | Alumina | 30.0 | 40.0 | 25.0 | 28.0 | 30.0 | 10.0 |
| (vol %) | Cordierite | 20.0 | 15.0 | 25.0 | 22.0 | 20.0 | 40.0 |
| | Glass | 50.0 | 45.0 | 50.0 | 50.0 | 50.0 | 50.0 |
| Maximum particle diameter of | | 2.5 | 4.1 | 2.0 | 1.8 | 0.8 | 2.5 |
| cordierite/maximum particle | | | | | | | |
| diameter of alumina | | | | | | | |
| Average particle diameter of | | 2.4 | 3.9 | 1.8 | 1.8 | 0.8 | 2.3 |
| cordierite/average particle | | | | | | | |
| diameter of alumina | | | | | | | |
| Crystalline peak | Anorthite | 3469 | 4126 | 2432 | 2930 | 1982 | 1774 |
| intensity (cps) by | Alumina | 6149 | 6532 | 5089 | 6002 | 6254 | 4811 |
| X-ray diffraction | Cordierite | 5395 | 4128 | 6150 | 4712 | 5450 | 6632 |
| Crystalline peak | Anorthite/(anorthite + | 0.23 | 0.28 | 0.18 | 0.21 | 0.14 | 0.13 |
| intensity ratio | alumina + cordierite) | | | | | | |
| by X-ray | | | | | | | |
| diffraction | | | | | | | |

| | | | | | | |
|---|---|---|---|---|---|---|
| Thermal expansion coefficient | 3.6 | 4.0 | 3.2 | 3.4 | 3.5 | 3.1 |
| (× 10⁻⁶/° C.) | | | | | | |
| Maximum value of three-point | 377 | 396 | 281 | 311 | 243 | 232 |
| bending strength (MPa) | | | | | | |

The glass ceramic substrate prepared as described above was crushed into a powder, and the X-ray diffraction peak intensities of each ceramic filler and precipitated crystals (anorthite) were measured from the XRD patterns obtained by an X-ray diffraction apparatus. Specifically, the X-ray diffraction peak intensity of the (2-20) crystal plane of the anorthite, the X-ray diffraction peak intensity of the (104) crystal plane of the alumina, and the X-ray diffraction peak intensity of the (100) crystal plane of the cordierite were measured. Note that, the presence of a halo pattern in the XRD pattern can determine whether the glass ceramic substrate contains a glass.

The thermal expansion coefficient is a thermal expansion coefficient in a temperature range of from −40° C. to +125° C., and is measured with a dilatometer.

The three-point bending strength is the strength measured on a sample having thickness of 3.0 mm using a method in accordance with JIS R1601 (2008). The measurement was performed on N=20 for each sample, and the highest value was taken as the strength value for the sample.

As seen from Table 1, the samples Nos. 1 to 4 have three-point bending strength of 250 MPa or more and a thermal expansion coefficient of 4.0×10⁻⁶/° C. or less. It is believed that this result is due to (X-ray diffraction peak intensity of the (2-20) crystal plane of the anorthite)/(X-ray diffraction peak intensity of the (2-20) crystal plane of the anorthite+X-ray diffraction peak intensity of the (104) crystal plane of the alumina+X-ray diffraction peak intensity of the (100) crystal plane of the cordierite) being 0.15 or more, and the incorporation of the alumina having high strength and the cordierite having a low thermal expansion effect, which are features of the present invention. Therefore, the sample Nos. 1 to 4 are suitable for a glass ceramic substrate to be used in a probe card. On the other hand, since in the samples Nos. 5 and 6, (X-ray diffraction peak intensity of the (2-20) crystal plane of the anorthite)/(X-ray diffraction peak intensity of the (2-20) crystal plane of the anorthite+X-ray diffraction peak intensity of the (104) crystal plane of the alumina+X-ray diffraction peak intensity of the (100) crystal plane of the cordierite) is less than 0.15, the three-point bending strength is less than 250 MPa. Therefore, the sample Nos. 5 and 6 are not suitable for a glass ceramic substrate to be used in a probe card.

### REFERENCE SIGNS LIST

1 glass ceramic circuit board
10 glass ceramic substrate
10a first main surface
10b second main surface
11 glass ceramic layer
20 internal conductor
21 interlayer electrode
22 via hole electrode
31, 32 electrode pad

1. A glass ceramic substrate comprising:
a glass;
a first ceramic filler;
a second ceramic filler; and
a crystalline material,
wherein the first ceramic filler is alumina,
the second ceramic filler is cordierite,
the crystalline material is anorthite, and
(X-ray diffraction peak intensity of a (2-20) crystal plane of the anorthite)/(X-ray diffraction peak intensity of the (2-20) crystal plane of the anorthite+X-ray diffraction peak intensity of a (104) crystal plane of the alumina+X-ray diffraction peak intensity of a (100) crystal plane of the cordierite) is 0.15 or more.

2. The glass ceramic substrate according to claim 1, which has three-point bending strength of 250 MPa or more.

3. The glass ceramic substrate according to claim 1, which has a thermal expansion coefficient in a temperature range of from −40° C. to +125° C. of 4.0×10⁻⁶/° C. or less.

4. The glass ceramic substrate according to claim 1, wherein a maximum particle diameter of the cordierite is larger than a maximum particle diameter of the alumina.

5. The glass ceramic substrate according to claim 4, wherein a value obtained by dividing the maximum particle diameter of the cordierite by the maximum particle diameter of the alumina is from 1.5 to 10.0.

6. The glass ceramic substrate according to claim 1, wherein an average particle diameter of the cordierite is larger than an average particle diameter of the alumina.

7. The glass ceramic substrate according to claim 6, wherein a value obtained by dividing the average particle diameter of the cordierite by the average particle diameter of the alumina is from 1.5 to 10.0.

8. The glass ceramic substrate according to claim 1, wherein the glass has a content of Al₂O₃ of 1.0 mol % or less.

9. The glass ceramic substrate according to claim 1, wherein the glass contains, as a glass composition, in mol %, from 50% to 80% of SiO₂, from 5% to 30% of B₂O₃, and from 3% to 25% of CaO.

10. A green sheet for a glass ceramic substrate comprising:
a glass powder;
a first ceramic filler; and
a second ceramic filler,
wherein the first ceramic filler is alumina,
the second ceramic filler is cordierite, and
a maximum particle diameter of the cordierite is larger than a maximum particle diameter of the alumina.

11. A green sheet for a glass ceramic substrate comprising:
a glass powder;
a first ceramic filler; and
a second ceramic filler,
wherein the first ceramic filler is alumina,
the second ceramic filler is cordierite, and
an average particle diameter of the cordierite is larger than an average particle diameter of the alumina.

12. A composite powder for a glass ceramic substrate comprising:
a glass powder;
a first ceramic filler; and
a second ceramic filler,
wherein the first ceramic filler is alumina,
the second ceramic filler is cordierite, and
a maximum particle diameter of the cordierite is larger than a maximum particle diameter of the alumina.

13. A composite powder for a glass ceramic substrate comprising:
a glass powder;
a first ceramic filler; and
a second ceramic filler,
wherein the first ceramic filler is alumina,
the second ceramic filler is cordierite, and
an average particle diameter of the cordierite is larger than an average particle diameter of the alumina.
